(19) United States
(12) Patent Application Publication
(10) Pub. No.: US 2011/0244634 A1
(43) Pub. Date: Oct. 6, 2011

(54) SEMICONDUCTOR PACKAGE AND METHODS OF MANUFACTURING THE SAME

(75) Inventors: Young-Lyong Kim, Seonganm-si (KR); Jong-Ho Lee, Hwaseong-si (KR); Cheul-Joong Youn, Seoul (KR); Eun-Chul Ahn, Yongin-si (KR)

(73) Assignee: Samsung Electronics Co., Ltd., Suwon-si (KR)

(21) Appl. No.: 13/103,553

(22) Filed: May 9, 2011

Related U.S. Application Data
(62) Division of application No. 12/484,491, filed on Jun. 15, 2009, now abandoned.

(30) Foreign Application Priority Data
Jun. 16, 2008 (KR) 10-2008-0056442

(51) Int. Cl. H01L 21/56

(52) U.S. Cl. 438/124; 257/E21.502

(57) ABSTRACT

A semiconductor package and a method of manufacturing the semiconductor package. The semiconductor package includes a first package that a first semiconductor chip is mounted on a front side of a first substrate and a redistributed pad including a first redistributed pad electrically connected to the first substrate and a second redistributed pad electrically connected to the first redistributed pad is disposed on the first semiconductor chip and a second package that a second semiconductor chip is mounted on a front side of a second substrate, the second package including a connection member electrically connected to the second redistributed pad. The connection member electrically connected to the redistributed pad electrically connects the first and second packages to each other.

### CROSS-REFERENCE TO RELATED APPLICATIONS

This application is a Divisional Application of U.S. patent application Ser. No. 12/484,491, filed on Jun. 15, 2009, which claims priority under 35 U.S.C. §119 of Korean Patent Application No. 2008-56442, filed on Jun. 16, 2008, the entire contents of which are herein incorporated by reference in their entirety.

### BACKGROUND

1. Field of the Invention

The exemplary embodiments disclosed herein relate to semiconductor devices and methods of manufacturing the same, and more particularly, to semiconductor devices of a package on package (POP) type and methods of manufacturing the same.

2. Description of the Related Art

In a semiconductor industry, as a requirement for smaller, thinner and higher capacity electronic devices using the semiconductor devices increases, a variety of package techniques have been appeared. One of the package techniques is a package technique that a plurality of semiconductor devices is vertically stacked to embody a high density chip stacking. This technique may have an advantage that semiconductor devices having a variety of functions can be integrated in a smaller area than a general package having one semiconductor chip.

However, a package technique integrating a plurality of semiconductor devices may have a lower reliability than a package technique integrating one semiconductor device. A technique stacking a package on a package, what is called a package on package (POP) technique, has been introduced to overcome a reliability problem and to embody a high density chip stacking. A package on package (POP) technique has an advantage that can reduce a malfunction of a final product because each semiconductor package passed a test. Therefore, it is necessary that a package on package (POP) technique is continuously developed to increase reliability and embody a high integration.

### SUMMARY

The present general inventive concept provides a semiconductor package and a method thereof.

Additional aspects and utilities of the present general inventive concept will be set forth in part in the description which follows and, in part, will be obvious from the description, or may be learned by practice of the general inventive concept.

Some exemplary embodiments provide a semiconductor package. The semiconductor package may include a first package that a first semiconductor chip is mounted on a front side of a first substrate and a redistributed pad including a first redistributed pad electrically connected to the first substrate and a second redistributed pad electrically connected to the first redistributed pad is disposed on the first semiconductor chip, and a second package that a second semiconductor chip is mounted on a front side of a second substrate, the second package including a connection member electrically connected to the second redistributed pad. The connection member electrically connected to the redistributed pad electrically connects the first and second packages to each other.

Some exemplary embodiments provide a semiconductor package. The semiconductor package may include an upper package including an external terminal and a lower package including a redistributed pad and a via hole exposing the redistributed pad. The external terminal is expanded into the via hole to be in contact with the redistributed pad, thereby electrically connecting the upper and lower package to each other.

Some exemplary embodiments provide a method of manufacturing a semiconductor package. The method may include providing an upper package including an external terminal, providing a lower package including a via hole where the external terminal is expanded and a redistributed pad electrically connected to the external terminal, and electrically connecting the upper and lower packages to each other by stacking the upper package on the lower package.

Some exemplary embodiments provide an electronic apparatus including a semiconductor package having an upper package including an external terminal, and a lower package including a redistributed pad and a via hole to expose the redistributed pad, wherein the external terminal may be expanded into the via hole to be in contact with the redistributed pad, such that the upper and lower packages are electrically connected to each other, and a control unit connected to the semiconductor package to store data and read data in or from the semiconductor package.

Some exemplary embodiments provide a semiconductor package including a package having a printed circuit board, at least one semiconductor chip mounted on the printed circuit board, and an external terminal mounted on the printed circuit board and electrically connected to the at least one semiconductor chip, and another package having another printed circuit board, at least one another semiconductor chip mounted on the another printed circuit board and electrically connected to the printed circuit board, and a redistributed pad formed on the another semiconductor chip and electrically connected to at least one of the another semiconductor chip and the another printed circuit board, wherein the distributed pad may be electrically connected to the external terminal of the package when the package and the another package are combined into a single integrated package.

The another package may further include a molding layer to cover the another semiconductor chip and a vie hole formed in the molding layer to expose the redistributed pad.

The external terminal of the package may be electrically connected to the redistributed pad through the via hole.

The via hole may be formed to face the external terminal from the another semiconductor chip.

The external terminal and the via hole may have different shape or dimension from each other.

The external terminal of the package may have a variable shape to increase an electrical connection area with the redistributed pad.

The external terminal may have a first shape before the package and the another package are combined, and a second shape after the package and the another package are combined.

The printed circuit board of the package may be disposed between the semiconductor chip of the package and the another semiconductor chip of the another package.

Some exemplary embodiments provide a semiconductor package including a package having a printed circuit board and an external terminal electrically connected to the at least one semiconductor chip, and another package having at least one another semiconductor chip and a redistributed pad formed on the another semiconductor chip. The external terminal may have a variable shape to be changed according to a combination of the package and the another package to form a single integrated package.

### BRIEF DESCRIPTION OF THE DRAWINGS

These and/or other aspects and utilities of the present general inventive concept will become apparent and more readily appreciated from the following description of the embodiments, taken in conjunction with the accompanying drawings of which:

FIGS. 1A through 1F are cross sectional views illustrating a method of manufacturing a semiconductor package according to an embodiment of the present general inventive concept.

FIGS. 2A through 2C are cross sectional views illustrating a method of manufacturing a semiconductor package according to an embodiment of the present general inventive concept.

FIGS. 3A through 3C are cross sectional views illustrating a method of manufacturing a semiconductor package according to an embodiment of the present general inventive concept.

FIGS. 4A through 4C are cross sectional views illustrating a method of manufacturing a semiconductor package according to an embodiment of the present general inventive concept.

FIGS. 5A and 5B are top plan views illustrating a portion of FIG. 1B.

FIGS. 6A and 6B are cross sectional views illustrating a portion of FIG. 1C.

FIG. 7A is a cross sectional view illustrating a method of manufacturing a semiconductor package according to an embodiment of the present general inventive concept.

FIG. 7B is a cross sectional view illustrating a method of manufacturing a semiconductor package according to an embodiment of the present general inventive concept.

FIG. 8 is a perspective view illustrating an electronic device with a semiconductor package according to an embodiment of the present general inventive concept.

FIG. 9 is a block diagram illustrating an electronic device with a semiconductor package according to an embodiment of the present invention general inventive concept

### DETAILED DESCRIPTION OF THE EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures. This general inventive concept may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first region/layer could be termed a second region/layer, and, similarly, a second region/layer could be termed a first region/layer without departing from the teachings of the disclosure.

The terminology used herein is for the purpose of describing particular embodiments only and is not intended to be limiting of the present general inventive concept. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Embodiments of the present general inventive concept may be described with reference to cross-sectional illustrations, which are schematic illustrations of idealized embodiments of the present general inventive concept. As such, variations from the shapes of the illustrations, as a result, for example, of manufacturing techniques and/or tolerances, are to be expected. Thus, embodiments of the present general inventive concept should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present general inventive concept.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

In the drawings, the thickness of layers and regions are exaggerated for clarity. It will also be understood that when an element such as a layer, region or substrate is referred to as being “on” or “onto” another element, it may lie directly on the other element or intervening elements or layers may also be present. Like reference numerals refer to like elements throughout the specification.

Spatially relatively terms, such as “beneath,” “below,” “above,” “upper,” “top,” “bottom” and the like, may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, when the device in the figures is turned over, elements described as below and/or beneath other elements or features would then be oriented (rotated 90 degrees or at other orientations) and the spatially relative descriptors used herein interpreted accordingly. As used herein, “height” refers to a direction that is generally orthogonal to the faces of a substrate.

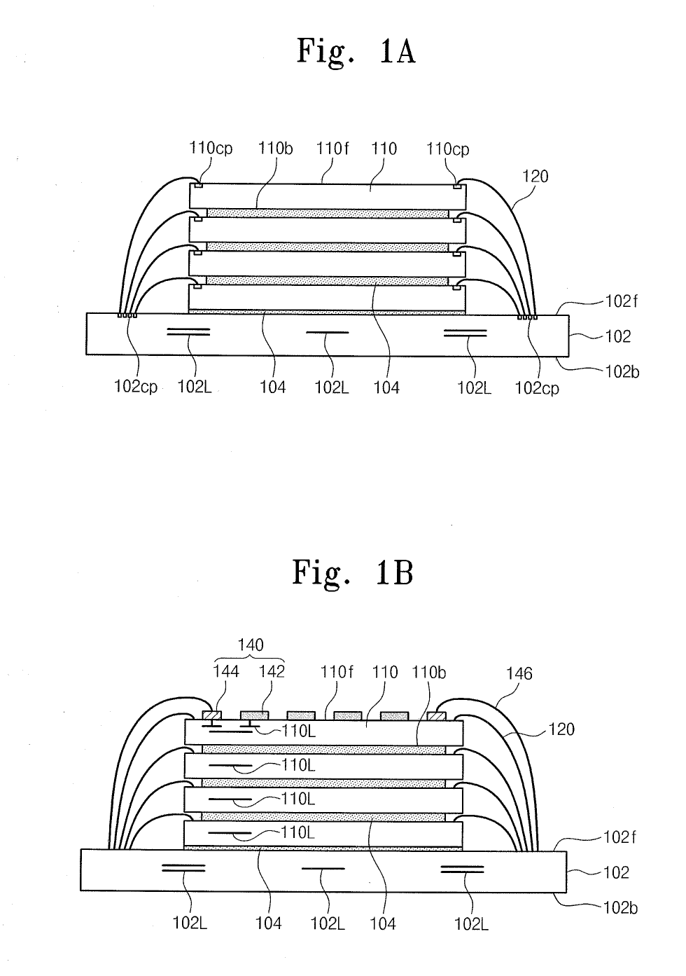

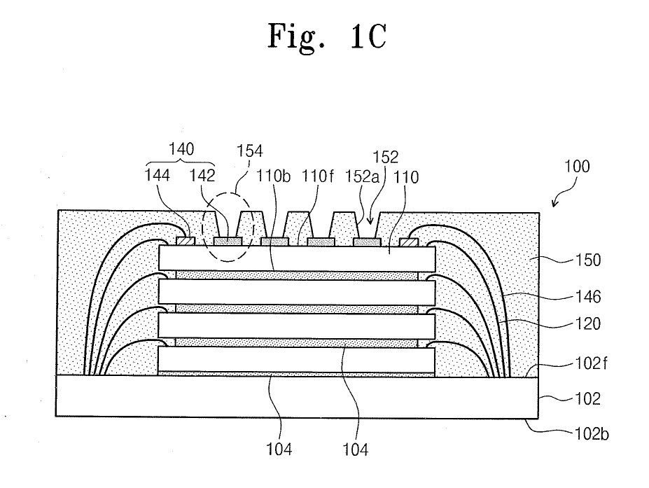

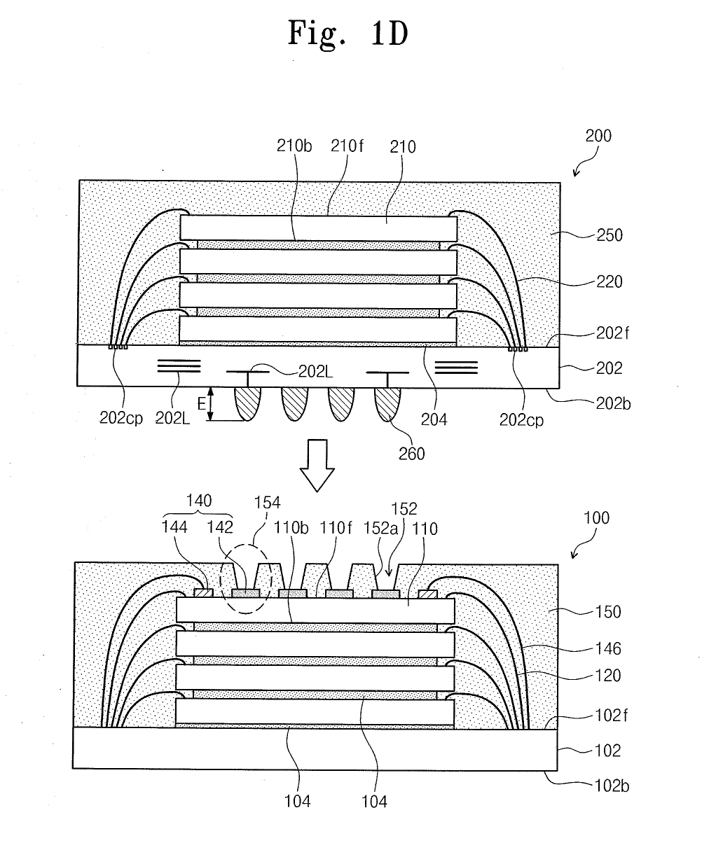

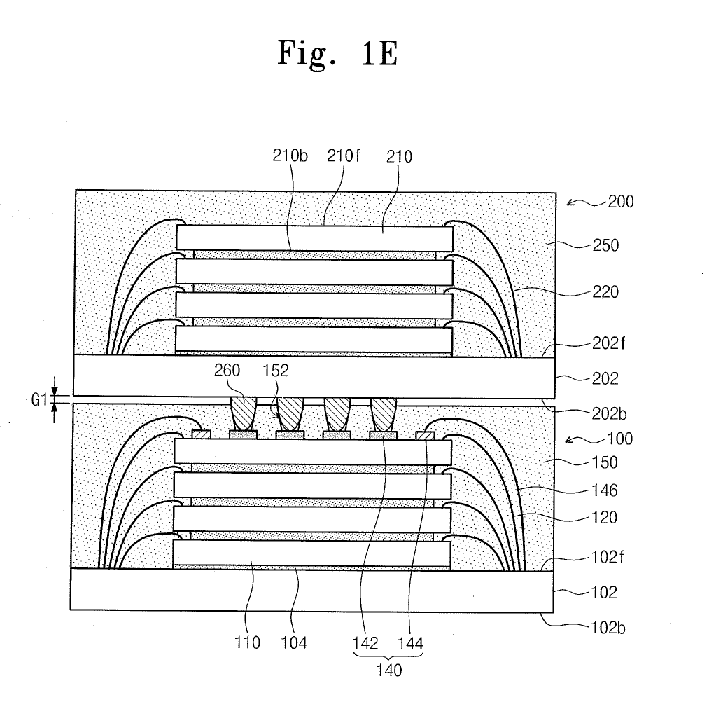

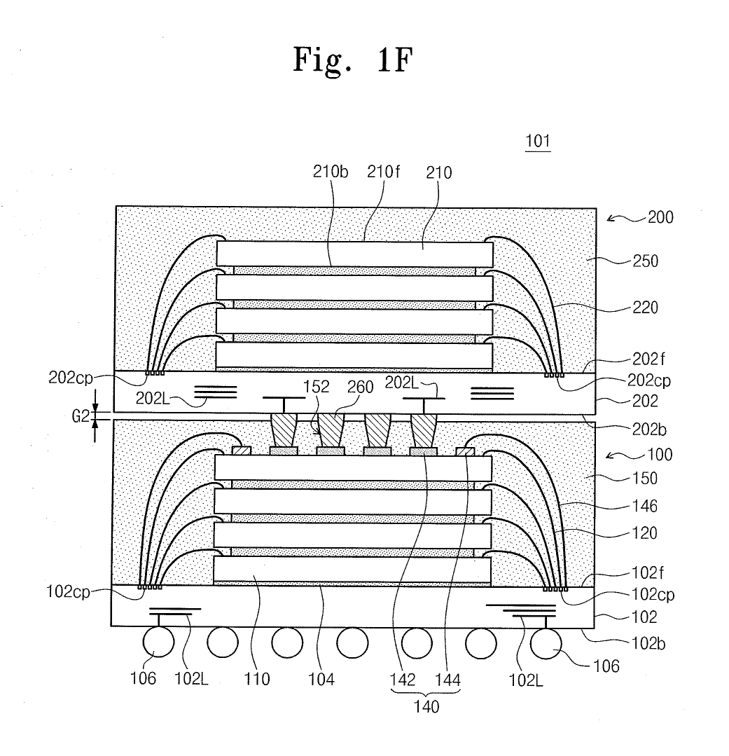

FIGS. 1A through 1F are cross sectional views illustrating a method of manufacturing a semiconductor package according to an embodiment of the present general inventive concept.

Referring to FIG. 1A, a first printed circuit board 102 including a front side 102f and a back side 102b is provided and at least one first semiconductor chip 110 is mounted on the front side 102f. The first chip 110 may be a memory chip or a logic chip. When a plurality of the first semiconductor chips 110 are stacked, one of the plurality of first semiconductor chips 110 may be memory chip and another may be a logic chip. In the present embodiment, a plurality of the first semiconductor chips 110 may be stacked on the front side 102f. A description discussed below may be applied when one first semiconductor chip 110 is mounted on the first printed circuit board 102.

The front side 102f of the first printed circuit board 102 is a side connectable to or formed with one or more semiconductor chips 110. As illustrated in FIG. 1A, one or more pads 102cp are formed on the front side 102f, and one or more pads 110cp are formed on the corresponding semiconductor chips 110 to connect the semiconductor chips 110 to corresponding pads 102cp through the corresponding bonding wires 120. The first printed circuit board 102 may further include one or more conductive lines to connect the pads 102cp to each other or to connect the pads 102cp to corresponding ones of solder balls 106 of FIG. 1F.

The plurality of the first semiconductor chips 110 may be stacked upside down on the front side 102f of the printed circuit board 102. For example, each of the plurality of the first semiconductor chips 110 may be stacked in a shape that an inactive surface 110b faces the front side 102f and an active surface 110f faces the above. An adhesive layer 104 may be interposed between the first printed circuit board 102 and the first semiconductor chip 110. Similarly, a plurality of adhesive layers 104 may be interposed between the first semiconductor chips 110. The plurality of the first semiconductor chips 110 and the first printed circuit board 102 may be electrically connected to each other by connection members, for instance a plurality of first bonding wires 120. Both edges of the bonding wire 120 may be in contact with pads 110cp and/or 102cp disposed on the active surface 110f and the front side 102f, respectively.

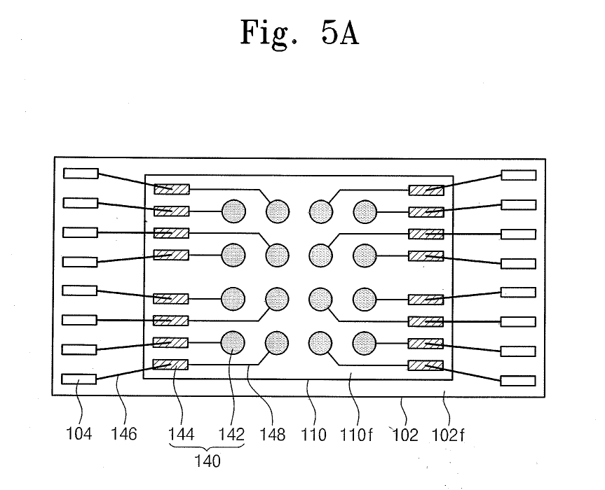

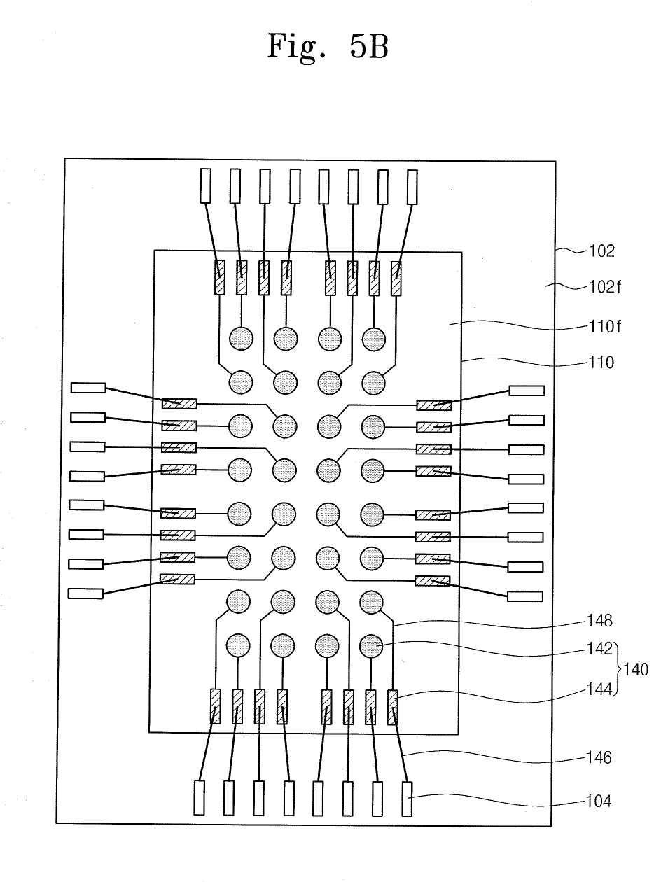

Referring to FIG. 1B, a plurality of redistributed interconnections 140 are disposed on an active surface 110f of the first semiconductor chip 110 of the top layer and an electrical connection member is formed to electrically connect the redistributed pad 140 to the first printed circuit board 102. The redistributed pad 140 may be formed of metal or alloy such as copper, gold, silver, platinum, etc. A bonding wire 146 may be formed as an example of an electrical connection member. In another embodiment, in a process of FIG. 1A, the first semiconductor chip 110 on which the redistributed pad 140 is previously formed may be stacked on the top layer. As described later, the redistributed pad 140 may be an example of the electrical connection member which connects a first semiconductor package (100 of FIG. 1F) to a second semiconductor package (200 of FIG. 1F). The redistributed pad 140 will be described in more detail in FIGS. 5A and 5Bb depicting a top plan of FIG. 1B.

Referring to FIG. 5A together with FIG. 1B, the redistributed pad 140 may include a plurality of first redistributed pads 144 disposed to be adjacent to both edges of the active surface 110f of the first semiconductor chip 110 and a plurality of second redistributed pads 142 occupying a central portion of the active surface 110f. The first redistributed pad 144 and the second redistributed pad 142 may be electrically connected to each other by a conductive line 148. For example, a plurality of the first redistributed pads 144 may be electrically connected to the first printed circuit board 102 through a plurality of the bonding wires 146. A plurality of pads 104 with which a plurality of bonding wires 146 are in contact may be disposed on both edges of front side 102f of the first printed circuit board 102. As described later, a second semiconductor package (200 of FIG. 1F) is in contact with the second redistributed pad 142. The number of the second redistributed pad 142 may be equal to the number of electrical connection interposer such as a solder ball (260 of FIG. 1D) electrically connecting the second semiconductor package (200 of FIG. 1F) to the first semiconductor package 100.

As illustrated in FIG. 5A, the pads 104 and the redistributed pads 140 are arranged symmetrically with respect to a center line of the semiconductor chip 110. The pads 104 are spaced apart from each other by a first distance, the first distributed pads 144 are spaced apart from each other by a second distance, and the second distributed pads 142 are spaced apart from each other by a third distance. The first, second, and third distances may be different from each other. However, the present general inventive concept is not limited thereto. The second distributed pads 142 may be arranged to form two lines with respect to a center line of the semiconductor chip 110. It is possible that the second distributed pads 142 may be arranged to form more than two lines with respect to a center line of the semiconductor chip 110.

As illustrated in FIG. 1B, one of the semiconductor chips 110 of a top layer may include one or more conductive lines 110L formed therein to connect the redistributed interconnections 140 to each other or another elements therein, such as the first printed circuit board 102, another printed circuit board, another semiconductor chip, or a memory unit disposed in the semiconductor chip 110. Other ones of the semiconductor chips 110 than the top layer may include one or more conductor lines to connect the pad 110cp to an internal element, such as a memory unit disposed in the semiconductor chip 110. The conductive lines 102L are formed on a surface of the first printed circuit board 102 or inside the first printed circuit board. Since the printed circuit board and the conductive lines are well known, detailed descriptions thereof will be omitted.

FIG. 5B illustrates a plurality of the first redistributed pads 144 disposed adjacent to all four edges of the active surface 110f of the first semiconductor chip 110. A plurality of pads 104 electrically connected to the plurality of the first redistributed pads 144 through the bonding wires 146 may be disposed on all four edges of the front side 102f of the first printed circuit board 102.

The pads 104 and the redistributed pads 140 are arranged symmetrically with respect to center lines of the semiconductor chip 110 corresponding to the four edges. The pads 104 are spaced apart from each other by a first distance, the first distributed pads 144 are spaced apart from each other by a second distance, and the second distributed pads 142 are spaced apart from each other by a third distance. The first, second, and third distances may be different from each other. However, the present general inventive concept is not limited thereto. The pads 104 and the redistributed pads 140 may have different shapes. The number of the second redistributed pad 142 may be equal to the number of electrical connection interposer such as a solder ball (260 of FIG. 1D) electrically connecting the second semiconductor package (200 of FIG. 1F) to the first semiconductor package 100.

Referring to FIG. 1C, a first molding layer 150 covering a plurality of the first semiconductor chips 110 may be formed on the front side 102f of the first printed circuit board 102. The first molding layer 150 may be formed of, for example, an epoxy molding compound (EMC). A portion of the first molding layer 150 is removed to form a plurality of via holes 152 to expose the second redistributed pads 142 therethrough. As a result, the first semiconductor package 100 including the redistributed pads 140, the via holes 152 and a plurality of the first semiconductor chips 110 stacked on thereon is completed.

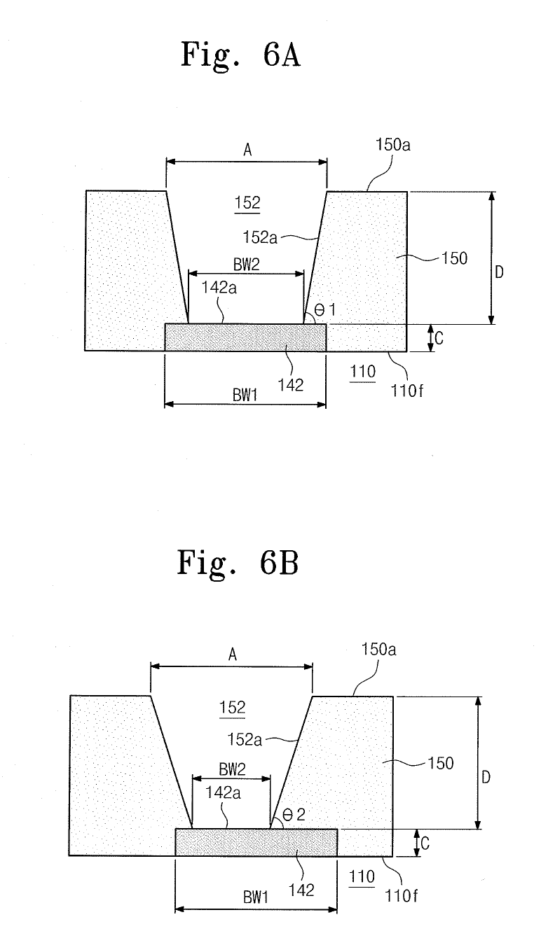

The via hole 152 may be formed using a laser drilling that does not need a mask and a photolithography process, and can form the via hole 152 at a high speed. When the via hole 152 is formed using the laser drilling, the via hole 152 may be formed to be inclined due to a laser characteristic. However, the present general inventive concept is not limited thereto. The via hole 152 can be formed using other methods than the laser drilling method. A description discussed above will be described more in detail in FIGS. 6A and 6B which are cross sectional views enlarging a portion of FIG. 1C.

Referring to FIGS. 6A and 1C, when a laser is focused on a top surface 150a of the first molding layer 150, a corresponding portion of the first molding layer 150 is gradually removed from the top surface 150a and a laser focus becomes more dimmed. Thus, the via hole 152 is considered to be formed to have a tapered shape. That is, area of cross section at top position 150a of the via hole 152 is greater than area of cross section at bottom position of the via hole 152. As described later in reference to FIG. 1D, a solder ball 260 of the second semiconductor package 200 is inserted into the via hole 152. The via hole 152 may have a shape corresponding to an external shape of the solder ball 260.

For example, an angle ⊖1 between an internal wall (side wall) 152a of the via hole 152 and the top surface 142a of the redistributed pad 142 may be in the range of 50 degrees to 90 degrees so that the solder ball 260 is easily inserted into the via hole 152. A depth (D) of the via hole 152 may be formed to be equal to or smaller than a protruding length (E of FIG. 1D) of the solder ball 260 so that the solder ball 260 inserted into the via hole 152 is in contact with the second redistributed pad 142.

Laser may damage the active surface 110f of the first semiconductor chip 110. Laser damage may be minimized or eliminated by establishing a width (A) of the via hole 152 to be equal to or smaller than a width (BW1) of the redistributed pad 142. Since the internal wall 152a defining the via hole 152 may be formed to be inclined with respect to a center line vertical to the top surface 150a to form the angle ⊖1, the width (A) of the via hole 152 is maximized at the top surface 152a.

Since the second redistributed pad 142 is formed of metal having physical properties of reflecting laser, the second redistributed pad 142 may not be damaged by laser. However, when a thickness (C) of the second redistributed pad 142 is thin, the second redistributed pad 142 is cut or holes are produced in the second redistributed pad 142 by laser. Moreover, the active surface 110f under the second redistributed pad 142 may be damaged. Damage on the second redistributed pad 142 and/or the active surface 110f caused by laser may be minimized by obtaining a thickness (C) of the second redistributed pad 142 to a certain extent. The second redistributed pad 142 may be formed to have a thickness of 3 μm to 10 μm. The second redistributed pad 142 may be increased or decreased depending on an energy magnitude of laser.

The redistributed pad 142 may have the width BW1, and also may have a width BW2 to be exposed through a portion of the internal wall 152a to an outside of the first molding layer 150 or the first semiconductor package 100. The width BW2 is narrower than the width BW1. The width BW2 of the redistributed pad 142 corresponds to a lower portion of the internal wall 152, and the width A corresponds to an upper portion of the internal wall, such that a shape of the via hole 150 becomes wider according to a distance from the redistributed pad 142. When the shape of the via hole 150 is a circular one, the width may be a diameter. When the shape of the via hole 150 is not a circular one, the width may be a length of a side of the via hole 150.

Referring to FIG. 6B, when a width (A) of the via hole 152 is established to be equal to or smaller than a width (B) of the second redistributed pad 142 and the via hole 152 is formed to be inclined, a possibility that laser damages the active surface 110f of the first semiconductor chip 110 may be reduced although laser is misaligned with the second redistributed pad 142 to a certain extent. When the via hole 152 has a smaller inclined angle ⊖2, a damage caused by laser may become smaller. The via hole 150 may have a center line disposed on a line vertical to the surface of the pad 142 other than a center line of the pad 142. The center line of the vial hole 150 may not overlap the center line of the pad 142 but deviated from the center line of the pad 142. The width A may be disposed outside of the pad 142 in a direction parallel to the pad 142 in the direction of the width A. That is, a portion of the via hole 150 may not overlap an area of the pad 142 or an upper portion of the via hole 150 is not disposed within an area of the pad 142 compared to the embodiment of FIG. 6A.

Referring to FIG. 1D, a second semiconductor package 200 is stacked on the first semiconductor package 100. The second semiconductor package 200 may be formed to have a structure which is similar to or equal to the first semiconductor package100. The second semiconductor package 200 may include a plurality of second semiconductor chips 210 stacked on a front side 202f of a second printed circuit board 202. The second semiconductor chips 210 are protected by a second molding layer 250. The plurality of second semiconductor chips 210 may be electrically connected to the second printed circuit board 202 by a plurality of second bonding wires 220.

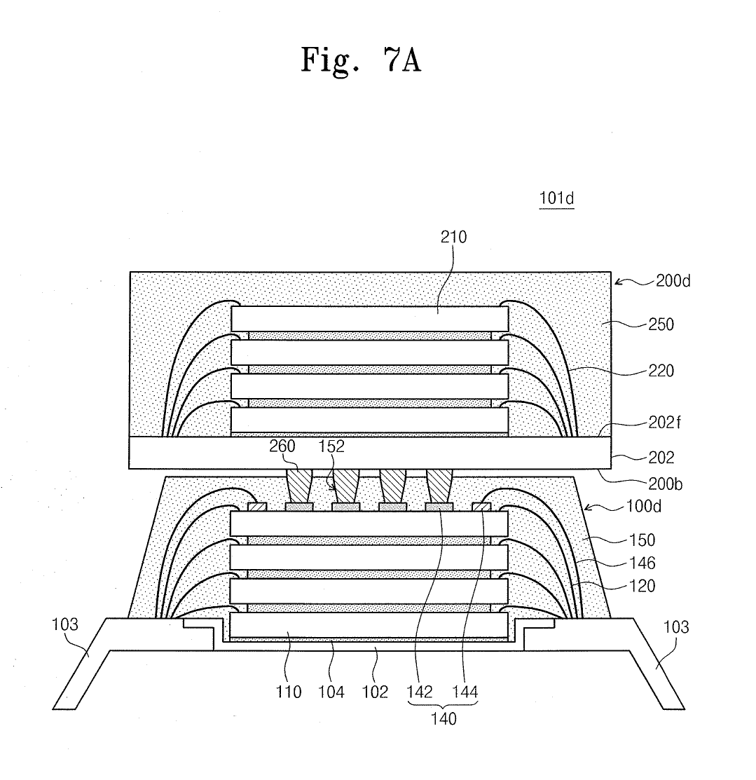

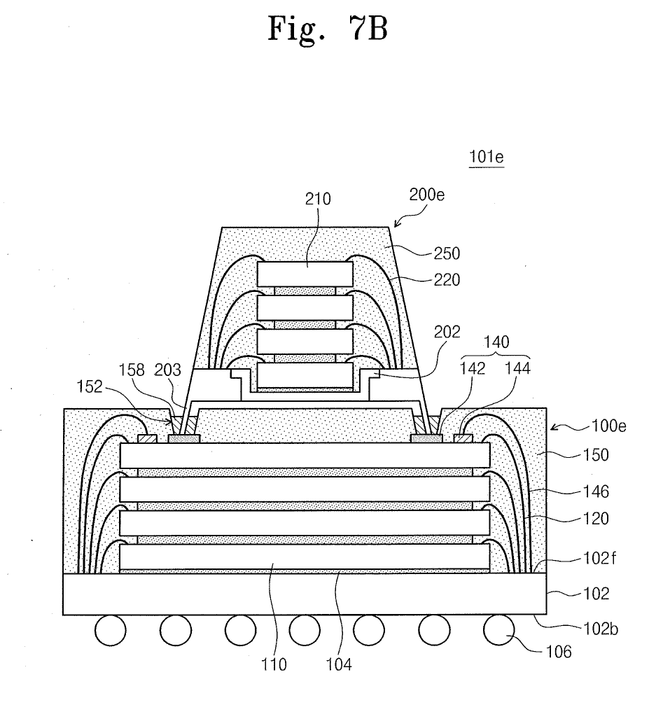

The second semiconductor package 200 may be a ball grid array (BGA) type package and may further include a plurality of solder balls 260 on a back side 202b of the second printed circuit board 202. In another embodiment, the second semiconductor package 200 may be a lead frame type package as described later referring to FIG. 7B. The solder ball 260 is one example of an interconnector electrically connecting the second semiconductor package 200 to the first semiconductor package 100. Here, the electrical interconnector may include a structure having a conductive material to be inserted into a plurality of via holes 152 to electrically connect the first and second semiconductor package 100 and 200. The electrical interconnector may include a solder bump or a lead frame. The number and an arrangement of the solder balls 260 may be equal to the number and an arrangement of the via holes 152. As described above referring to FIG. 6A, a protruding length (E) of the solder ball 260 may be equal to or greater than a depth (D) of the via hole 152.

The solder ball 260 protrudes from a bottom of the back side 202b of the second printed circuit board 202 by a protruding length E toward the first semiconductor package 100. A shape or dimension of the solder ball 260 is suitable to be inserted into the vial hole 152 such that a distal end of the solder ball 260 contacts the pad 142 when the second semiconductor package 200 is stacked and coupled to the first semiconductor package 200.

Although FIG. 1D illustrates a redistributed pad and a via hole, it is possible that the redistributed pad and the via hole may not be included in the second semiconductor package 200 of the present embodiment. However, when a third semiconductor package is stacked on the second semiconductor package 200, a redistributed pad may be further formed on an active surface 210f of the second semiconductor package 200 of the top layer and a via hole exposing the redistributed pad may be further formed on the second molding layer 250.

The second semiconductor package 200 is stacked on the first semiconductor package 100, so that a plurality of solder balls 260 are inserted into corresponding ones of a plurality of via holes 152. As a result, the plurality of solder balls 260 are physically or electrically in contact with a plurality of second redistributed pads 142.

The second printed circuit board 202 may have one of the conductive lines 202L to connect one or more pads 202cp to corresponding ones of the solder balls 260. Each semiconductor chips 110 may include one or more conductive lines 210 formed therein to connect the pads 202cp to corresponding memory circuit units of the respective semiconductor chips 210. Since the printed circuit board and the conductive lines are well known, detailed descriptions thereof will be omitted

Referring to FIG. 1E, a physical contact between the solder ball 260 and the second redistributed pads 142 may not provide a complete electrical connection. The physical contact between the solder ball 260 and the second redistributed pads 142 may cause a comparatively great contact resistance and a physical contact may not be realized because of the contact resistance. Thus, a complete electrical connection between the solder ball 260 and the second redistributed pads 142 may be realized by performing a reflow process. A gap G1 between the first and second semiconductor packages 100 and 200 may be formed because of differences in shape or dimension, or the gap G1 may be formed because of a difference and a protruding length (E of FIG. 1D) of the solder ball 260 and a depth (D of FIG. 6A) of the via hole 152.

It is possible that a gap may be formed because of difference in width. That is, a width of the solder ball 260 is wider than a width of the via hole 150 between widths A and BW2. Accordingly, it is possible that a lower portion of the solder ball 260 may not contact an upper portion of the pad 142.

Referring to FIG. 1F, a reflow process is performed to generate a metal connection or a metal compound between the solder ball 260 and the second redistributed pad 142, thereby embodying a complete electrical connection between the solder ball 260 and the second redistributed pad 142. A reflow process may be performed at a temperature of 200 degrees centigrade to 300 degrees centigrade. However, the present general inventive concept is not limited thereto. The reprocess temperature may be variable according to a material of the solder ball 260. The second semiconductor package 200 is electrically connected to the second redistributed pad 142 by the solder ball 260, and the second redistributed pad 142 is electrically connected to the first redistributed pad 144 which is electrically connected to the first printed circuit board 102. Therefore, the second semiconductor package 200 may be electrically connected to the first semiconductor package 100 through the solder ball 260 and the redistributed pad 140. The gap G1 and G2 may be a same. However, it is possible that the gap G1 and gap G2 may be changed or different.

During the reflow process, it is possible that an original shape of the solder ball 260 can be changed to a shape corresponding to the via hole 152. Also, it is possible that a width E of the solder ball 260 may be changed to contact the pad 142 for electrical connection.

A semiconductor package 101 of a package on package (POP) type and a fan-in stacking type that the second semiconductor package 200 is stacked to the first semiconductor package 100 may be completed by a series of the processes described above. A plurality of solder balls 106 may selectively be further attached to the back side 102b of the first printed circuit substrate 102 as an external terminal.

When the solder ball 260 of the second semiconductor package 200 is coupled or bonded to the pad 142 of the first semiconductor chip 100 through the via hole 152, a bonding force between them keeps the first semiconductor package 100 and the second semiconductor package 200 to be electrically or physically connected to each other as a single integrated body, that is, a single semiconductor package.

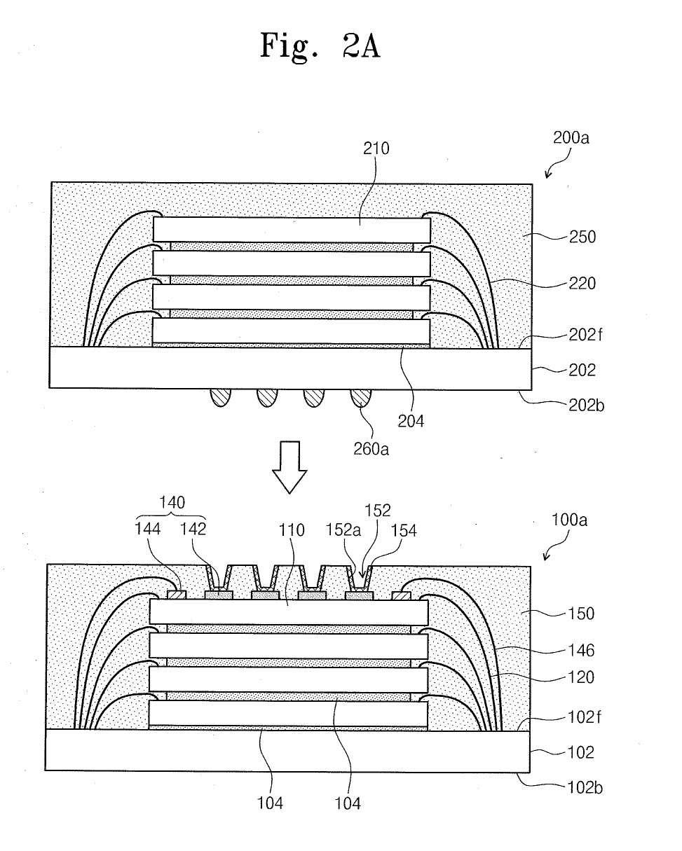

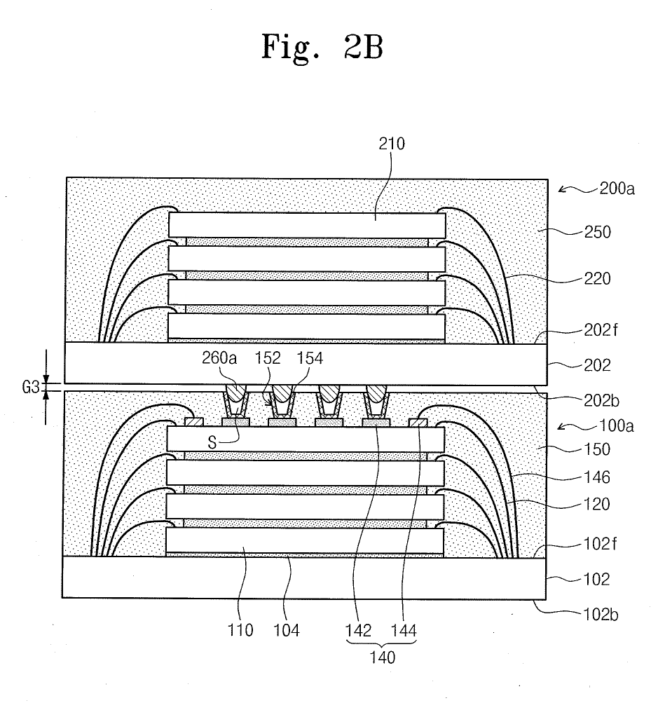

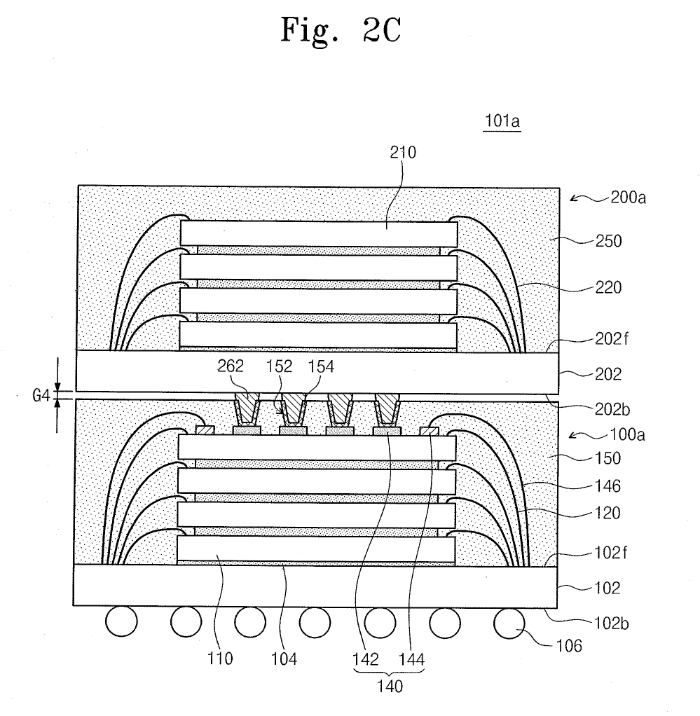

FIGS. 2A through 2C are cross sectional views illustrating a method of manufacturing a semiconductor package according to an embodiment of the present general inventive concept. Since the embodiment of FIGS. 2A through 2C is similar to the embodiment of FIGS. 1A through 1F and FIGS. 5A through 6B, description of common features already discussed in the embodiment of FIGS. 1A through 1F and FIGS. 5A through 6B will be omitted or briefly described.

Referring to FIG. 2A, a first semiconductor package 100a and a second semiconductor package 200a are provided to be combined to form a single semiconductor package. The first semiconductor package 100a may include one or more semiconductor chips and a first redistributed pad 144 and a second redistributed pad 142 on a first semiconductor chip 110 of a top layer among the semiconductor chips. A portion of a first molding layer 150 is removed to form a via hole 152 to expose a second redistributed pad 142. Unlike the first embodiment, the first semiconductor package 100a may further include a metal layer 154 in the via hole 152. The metal layer 154 may be formed using an electroplating method or a deposition method. The metal layer 154 may be formed on an inner wall 152a to define the vial hole 152. Also, the metal layer 154 may be formed on the inner wall 152a and the second redistributed pad 142.

The metal layer 154 may have a first portion to correspond to the inner wall 152a and a second portion to correspond to the second redistributed pad. The first portion of the metal layer 154 has a first thickness and the second portion of the metal layer 154 has a second thickness. The thicknesses of the first portion and the second portion may be same. However, the present general inventive concept is not limited thereto. The thicknesses may be different. An upper portion of the first portion of the metal layer 154 may have a width wider than a width of the second portion of the metal layer 154.

The second semiconductor package 200a may have a BGA structure similar to the second semiconductor package 200 of the embodiment of FIGS. 1A-1F. The second semiconductor package 200a may include a plurality of solder balls 260a on a back side 202b of a second printed circuit board 202. The solder ball 260a of this embodiment may not have a shape to be inserted into the vial hole 152 and , the solder ball 260a inserted into the via hole 152 may not have a width or a depth to be physically or electrically in contact with the second redistributed pad 142. As will be described later, since the embodiment of FIGS. 2A-2C includes a metal layer 154 that can wet the solder ball 260a, such that a via (262 of FIG. 2c) can be formed to fill the via hole 152 by performing a reflow of the solder ball 260a. The solder ball 260a may have a sufficient volume that can fill the via hole 152 during a reflow process.

A length of the solder ball 260a may be shorter than a depth of the via hole 252, and a shape or dimension of the solder ball 260a is different from a shape or dimension of the via hole or the metal layer 154. Therefore, a distal end of the solder ball 260a does not contact the pad 142 when the second semiconductor package 200 is initially disposed on the first semiconductor package 100. It is possible that there is an initial electrical contact area formed between the solder ball 260a and the metal layer 154. However, the initial electrical contact area can be variable, changed, or expanded to a second electrical contact area which is larger than the initial electrical contact area such that a sufficient electrical contact can be formed between the solder ball 260a and the metal layer 154 to transmit data between the first semiconductor package 100a and the second semiconductor package 200a. It is possible that the initial electrical contact area is enough to provide the data passage between the first semiconductor package 100a and the second semiconductor package 200a. Since the second electrical contact area is formed for electrical connection and a bonding force is formed by the reflow process between the first semiconductor package 100a and the second semiconductor package 200a, an electrical connection and a mechanical coupling are provided to the first semiconductor package 100a and the second semiconductor package 200a to form a single integrated semiconductor package.

Referring to FIG. 2B, the second semiconductor package 200a is stacked on the first semiconductor package 100a so that the solder ball 260a is inserted into the via hole 152. At this time, the solder ball 260a may be physically not in contact with the second redistributed pad 142.

However, it is possible that at least a portion of the solder ball 260a can contact the second redistributed pad 142 through the metal layer 154. In this case, a space S is formed between the solder ball 260a and the metal layer 154 and a gap G3 can be made between the second semiconductor package 200a and the first semiconductor package 100a as illustrated in FIG. 2B.

Referring to FIG. 2C, material constituting the solder ball 260a is expanded into the via hole 152 to fill the via hole 152 by performing a reflow process. At this time, since the metal layer 154 is formed in the via hole 152, the solder ball 260a may be wetted. As a result, the solder ball 260a is expanded by a reflow process to form a via 262 filling a vacant space of the via hole 152. Since the solder ball 260a is expanded to fill a vacant space of the via hole 152, a gap G4 (or G2 of FIG. 2C) after a reflow process may be different from a gap G3 (or G1 of FIG. 2b) before a reflow process.

At least a portion of the solder ball 260a can be changed from a solid state to a wet state. The solder ball 260a can be deformed to change a shape corresponding to the metal layer 154. The space S of FIG. 2B may be diminished or removed as illustrated in FIG. 2C.

A semiconductor package 101a of a package on package (POP) type and a fan-in stacking type that the second semiconductor package 200a is stacked to the first semiconductor package 100a through a redistributed pad 140 and the via 262 is completed by a series of the processes described above.

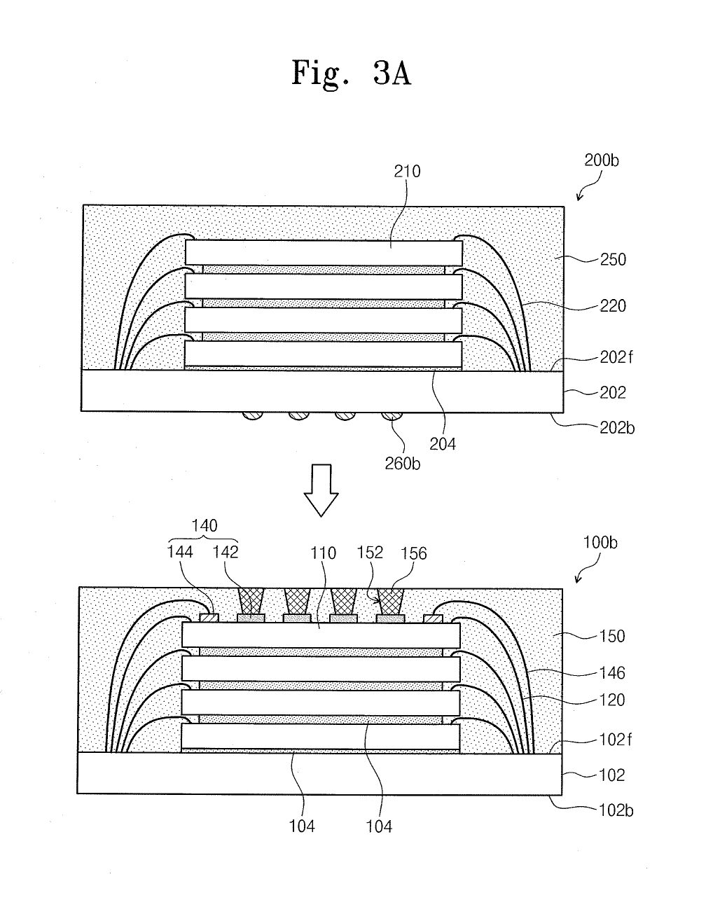

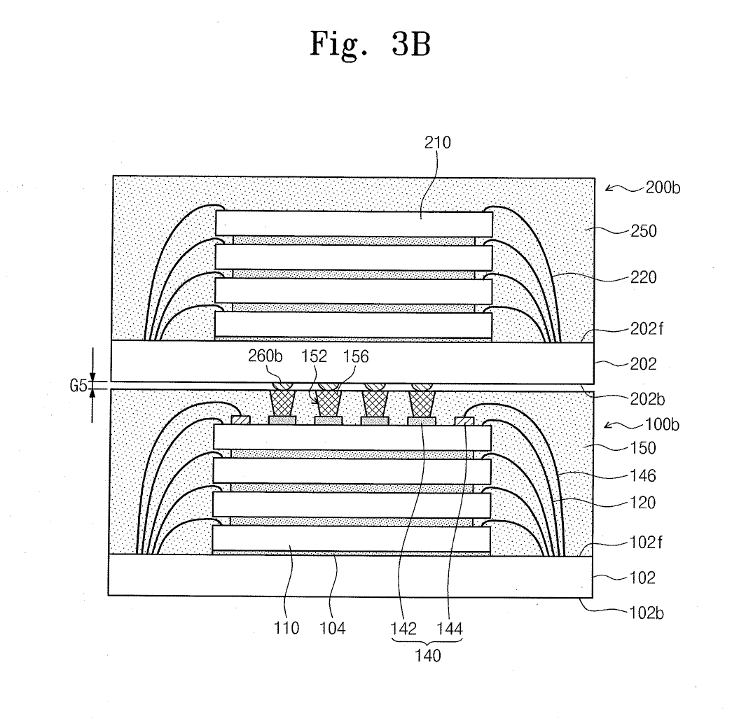

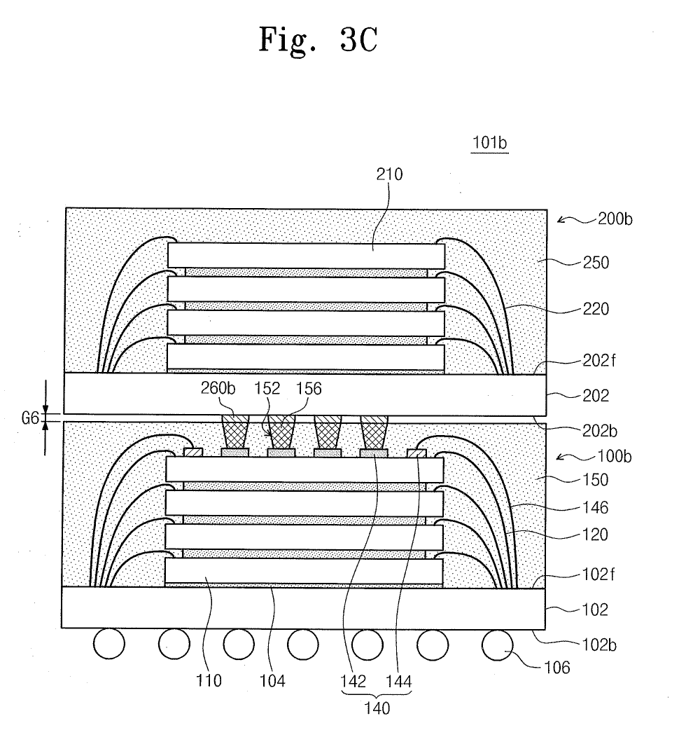

FIGS. 3A through 3C are cross sectional views illustrating a method of manufacturing a semiconductor package according to an embodiment of the present general inventive concept. Since this embodiment of FIGS. 3A-3C is similar to the embodiments of FIGS. 1A-2C and FIGS. 5A-6B, description of common features already discussed in these embodiments will be omitted or briefly described.

Referring to FIG. 3A, a first semiconductor package 100b and a second semiconductor package 200b are provided to form a single integrated semiconductor package. The first semiconductor package 100b may include a plurality of semiconductor chips and a first redistributed pad 144 and a second redistributed pad 142 on a first semiconductor chip 110 of a top layer. A portion of a first molding layer 150 is removed to form a via hole 152 to expose the second redistributed pad 142. The first semiconductor package 100b includes a via 156 formed by filling the via hole 152 with a conductor. The via 156 can fill at least a portion of an inside of the via hole 152. Since a solder ball is not inserted into the via hole 152, the solder ball may have a shape and a structure different from the vial hole regardless of a shape or structure of the via hole.

The second semiconductor package 200b may have a structure similar to the second semiconductor package 200 of the embodiment of FIGS. 1A-1F. The second semiconductor package 200b may be a package of a BGA type including a plurality of solder balls 260b on a back side 202b of a second printed board 202. The second semiconductor package 200b may not have limitation that the solder ball 260b should have a suitable shape to be inserted into the via hole 152. Also, since the solder ball 260b does not reflow into the via hole 152, a volume of the solder ball 260b can be variable or is not be limited to a shape of the via hole 152. The number and an arrangement of the solder ball 260b may be equal to the number and an arrangement of the via hole 152.

Referring to FIG. 3B, a plurality of solder balls 260b are physically in contact with a plurality of via 156 by stacking the second semiconductor package 200b on the first semiconductor package 100b.

Referring to FIG. 3C, a reflow process is performed to generate a metal connection or a metal compound between the solder ball 260b and the via 156, thereby embodying a complete electrical connection between the solder ball 260b and the via 156. A semiconductor package 101b of a package on package (POP) type and a fan-in stacking type that the second semiconductor package 200b is electrically connected to the first semiconductor package 100b through a redistributed pad 140 and the via 156 is completed by a series of the processes described above.

As illustrated in FIGS. 3B and 3C, a gap G5 and a gap G6 may be different. However, it is possible that the gap G5 and the gap G6 may be same.

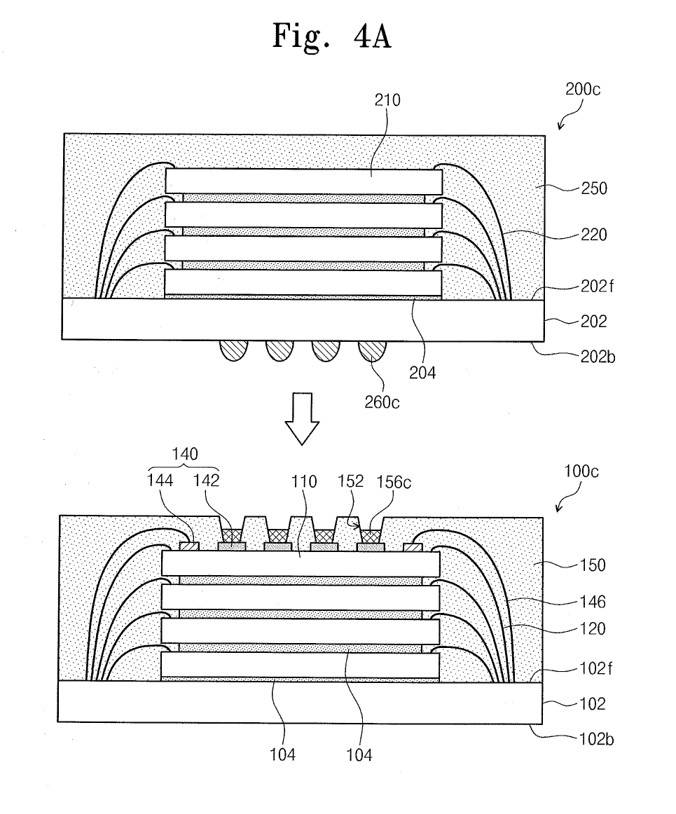

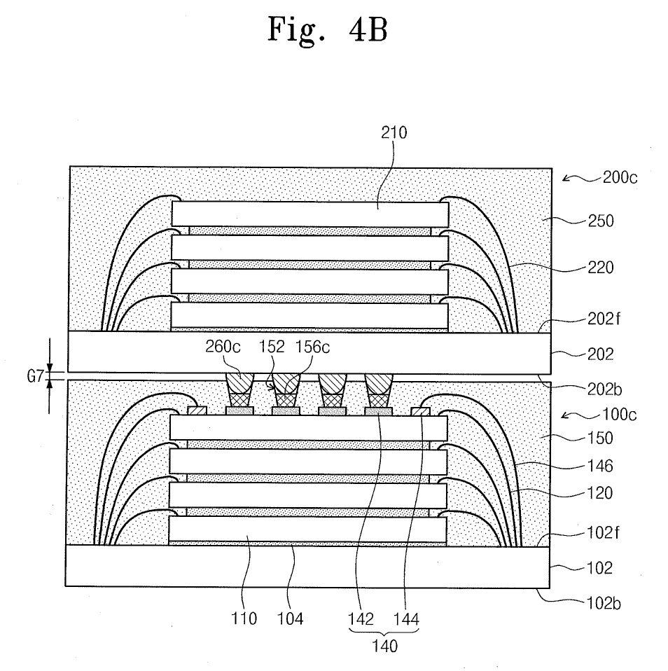

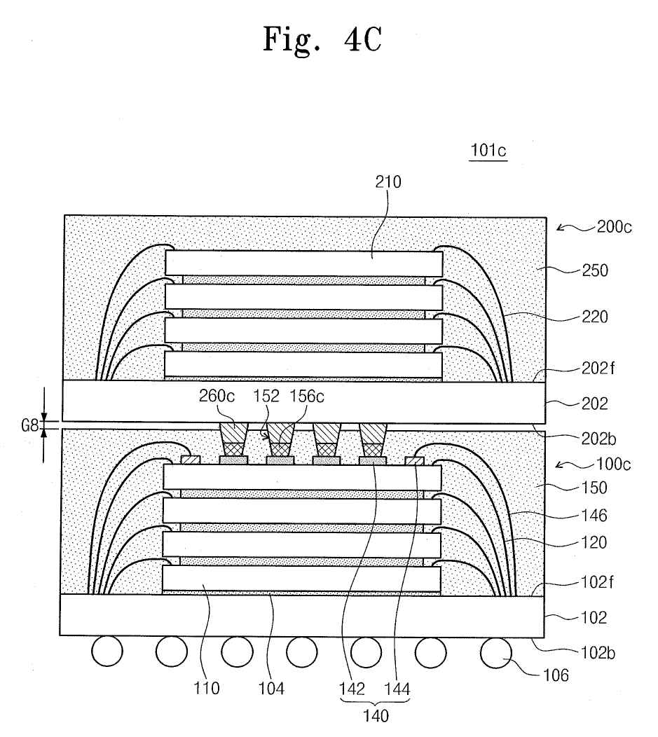

FIGS. 4A through 4C are cross sectional views illustrating a method of manufacturing a semiconductor package according to an embodiment of the present general inventive concept. Since this embodiment is similar to the embodiment of FIGS. 3A-3C, description of common features already discussed in the embodiment of FIGS. 3A-3C will be omitted or briefly described.

Referring to FIG. 4A, a first semiconductor package 100c and a second semiconductor package 200c are provided to form a single monolithic semiconductor package. The first semiconductor package 100c may have a structure similar to the first semiconductor package 100b of the embodiment of FIGS. 3A-3C. The first semiconductor package 100c may include a via 156c formed by filling a portion of a via hole 152 with a conductor. For example, since a conductor may not fill all portion of the via hole 152 or may fill only a lower portion of the via hole 152, the via 156c filling a lower portion of the via hole 152 may be formed.

The second semiconductor package 200c may have a structure similar to the second semiconductor package 200b of the embodiment of FIGS. 3A-3C. A solder ball 260c of the forth embodiment may be inserted into an upper portion of the via hole 152 not filled by the via 156c and may be directly in contact with the via 156c. The number and an arrangement of the solder ball 260c may be equal to the number and an arrangement of the via hole 152.

Referring to FIG. 4B, the solder ball 260 is inserted into the upper portion of the via hole 152 to be physically in contact with the via 156 by stacking the second semiconductor package 200c on the first semiconductor package 100c.

Referring to FIG. 4C, a reflow process is performed to generate a metal connection or a metal compound between the solder ball 260c and the via 156c, thereby embodying a complete electrical connection between the solder ball 260c and the via 156c. A semiconductor package 101c of a package on package (POP) type and a fan-in stacking type that the second semiconductor package 200c is electrically connected to the first semiconductor package 100c through a redistributed pad 140 and the via 156c is completed by a series of the processes described above. As illustrated in FIGS. 4B and 4C, a gap G7 and a gap G8 may be different. However, it is possible that the gap G7 and the gap G8 may be same.

FIG. 7A is a cross sectional view illustrating a method of manufacturing a semiconductor package according to an embodiment of the present general inventive concept. Since this embodiment is similar to the embodiment of FIGS. 1A-1F, description of common features already discussed in the embodiment of FIGS. 1A-1F will be omitted or briefly described.

Referring to FIG. 7A, a second semiconductor 200d may be stacked on a first semiconductor package 100d using a series of the processes described referring to FIGS. 1A through 1F. The second semiconductor package 200d may be a package, for example a package of a ball grid array (BGA) type, having a structure equal to the second semiconductor package 200 of the first embodiment. The first semiconductor package 100d may have a structure similar to the first semiconductor package 100 of the first embodiment. Unlike the first embodiment, the first semiconductor package 100d may be a package of a lead frame type. The first semiconductor package 100d may have a lead frame 103 as an external terminal. The lead frame 103 may be electrically connected to a first semiconductor chip 110 through a bonding wire 120. The second semiconductor package 200d may be electrically connected to the first semiconductor package 100d through a redistributed pad 140.

According to the present embodiment, the second semiconductor package 200d of a ball grid array (BGA) type may be stacked on the first semiconductor package 100d of a lead frame type. A semiconductor package 101d of a package on package (POP) may be embodied by stacking packages of different types.

FIG. 7B is a cross sectional view illustrating a method of manufacturing a semiconductor package according to an embodiment of the present general inventive concept. Since this embodiment is similar to the embodiment of FIGS. 1A-6B, description of common features already discussed in the embodiment of FIGS. 1A-6B will be omitted or briefly described.

Referring to FIG. 7B, a second semiconductor 200e may be stacked on a first semiconductor package 100e and electrically connected to each other using a series of the processes described referring to FIGS. 1A through 1F. The first semiconductor package 100e may have a structure equal to the first semiconductor package 100 of the embodiment of FIGS. 1A-1F. The second semiconductor package 200e may be a package of a lead frame type. The second semiconductor package may have a lead frame 203 instead of a solder ball as an external terminal. The lead frame 203 may be electrically connected to a second semiconductor chip 210 through a second bonding wire 220.

The lead frame 203 is inserted into a via hole 152 to electrically connect with a second redistributed pad 142, thereby electrically connecting the second semiconductor package 200e to the first semiconductor package 100e. The via hole 152 may be filled with a conductor 158 such as metal or a solder ball paste to firmly adhere the lead frame 203 to the second redistributed pad 142. The conductor 158 may fill a portion of the via hole 152 or all of the via hole 152.

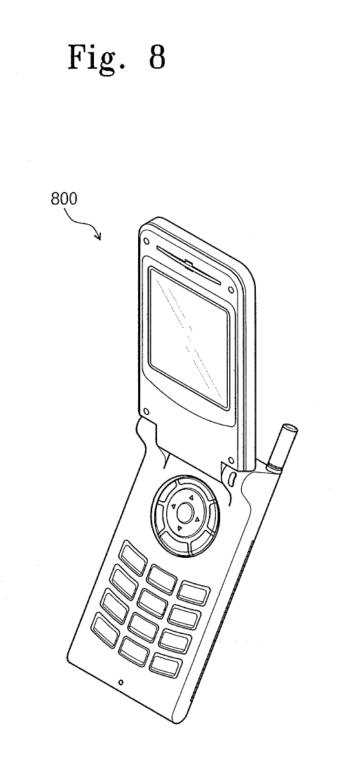

FIG. 8 is a perspective view illustrating an electronic device 800 having a semiconductor package according to an embodiment of the present general inventive concept.

Referring to FIG. 8, the semiconductor packages 101 to 101e according to the embodiments of the present general inventive concept may be used in the electronic device 800, such as a cell phone 1000. The cell phone 1000 may include a variety of functions such as a MP3 player, a camera, a digital multimedia broadcast, a wireless internet, a mobile banking besides a phone call. A plurality of semiconductor chips may need to be loaded on the cell phone 1000 to perform a variety of functions. In this case, a variety of functions may be embodied by loading the semiconductor packages 101 to 101e according to the embodiments of the present general inventive concept on the cell phone 1000. The electronic device 800 to which the semiconductor packages 101 to 101e according to the embodiments of the present general inventive concept are applied are not limited to the cell phone 1000 and may be a notebook computer, a personal multimedia player (PMP), a MP3 player, a camcorder, a memory stick, a memory card.

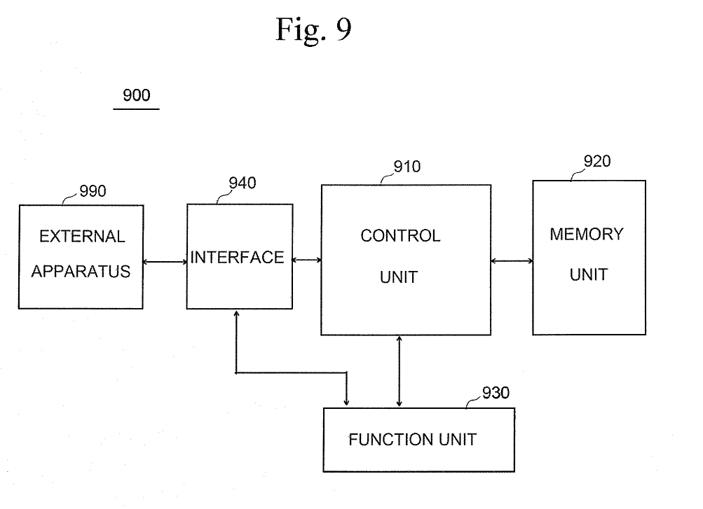

FIG. 9 illustrates an electronic apparatus 900 useable with a semiconductor package according to an embodiment of the present general inventive concept. The electronic apparatus may be the apparatus 800 of FIG. 8. However, the present general inventive concept is not limited thereto. As described above, the electronic apparatus may be other apparatuses having its own functions. For example, if the electronic apparatus is a cell phone or mobile phone, the electronic apparatus may have a function unit to perform a telephone function circuit and mechanism. If the electronic apparatus is a memory stick, the electronic apparatus may have having a housing, the housing including a terminal, such as a USB terminal formed on the housing, and a memory unit disposed in the housing to store data and output data through the terminal.

The electronic apparatus 900 may include a control unit 910, a memory unit 920, a function unit 930, and an interface unit 940 to communicate with an external apparatus 990 to transmit data read from the memory unit 920 and to receive data to be stored in the memory unit 920. The above described semiconductor packages of FIGS. 1A-7B can be used as the memory unit 920 or the control unit 910. It is possible that the memory unit 920 may include another memory unit which is different from the above described semiconductor packages of FIGS. 1A-7B by having a different structure and performing a different recording and reading method. It is possible that when the function unit 930 requires an internal memory unit, the above described semiconductor packages of FIGS. 1A-7B can be used as the internal memory unit of the function unit 930. The function unit 930 may a circuit and mechanism to perform the above described functions. Since the function unit 930 is well known, detailed descriptions thereof will be omitted.

When the electronic apparatus 900 is a cell phone, the interface unit 940 and/or the function unit 930 may be a wired or wireless communication device to communicate with the external apparatus 990, and the function unit 930 may include a display screen and an audio terminal to output sound according to data stored in the memory unit 920 or data received from the external apparatus 990. The function unit may have an input unit through a user inputs a command or data to perform a function of the cell phone. Also, the function unit 930 may have a display screen to display an image according to data input from the input unit, received from the external apparatus 990, or read from the memory unit 920. It is also possible that the external apparatus 990 can be a station for wireless transmission between cell phones. It is also possible that the external apparatus 990 can be an Internet service provider to provide an Internet connection or service to the electronic apparatus 900.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A method of manufacturing a semiconductor package comprising:
providing an upper package including at least one first semiconductor mounted on a first substrate and an external terminal electrically connected to the first substrate;
providing a lower package including at least one second semiconductor mounted on a second substrate, a redistributed pad electrically connected to the at least one second semiconductor, and a molding layer covering the at least one second semiconductor and having a via hole to expose the redistributed pad; and
stacking the upper package on the lower package to electrically connect the upper and lower packages to each other.

2. The method of claim 1, wherein providing the lower package comprises:
stacking a plurality of the second semiconductor chips on a front side of the second substrate;
forming the redistributed pad including a first redistributed pad which is disposed on an edge of an active surface of a semiconductor chip of the top layer among the plurality of semiconductor chips and is electrically connected to the second substrate, and a second redistributed pad which is disposed on a central portion of the active surface and is electrically connected to the first redistributed pad;
forming the molding layer molding the plurality of the second semiconductor chips on the front side of the second substrate; and
removing a portion of the molding layer to form the via hole exposing the second redistributed pad.

3. The method of claim 2, wherein forming the via hole comprises:
removing a portion of the molding layer using a laser so that a width of the via hole at a top surface of the molding layer is greater than a width of the via hole at the second redistributed pad.

4. The method of claim 3, wherein forming the via hole further comprises forming a width of the via hole to be equal to or smaller than a width of the second redistributed pad.

5. The method of claim 1, wherein electrically connecting the upper and lower packages to each other comprises:
inserting the external terminal into the via hole to directly contact the second redistributed pad; and
reflowing the external terminal to combine the external terminal with the second redistributed pad.

6. The method of claim 1, wherein electrically connecting the upper and lower packages comprises:
forming a metal layer in the via hole;
inserting the external terminal into the via hole;
reflowing the external terminal to wet the a material of the external terminal to the metal layer; and
expanding the material of the external terminal into the via hole to form a via by filling the via hole with the material of the external terminal.

7. The method of claim 1, wherein electrically connecting the upper and lower packages comprises:
filling the via hole with a conductor to form a via;
directly contacting the external terminal with the via; and
reflowing the external terminal to combine the external terminal with the via.

8. The method of claim 1, wherein electrically connecting the upper and lower packages comprises:
inserting the external terminal into the via hole to directly contact the second redistributed pad; and
forming a conductor filling the via hole to fix the external terminal to the redistributed pad.
